(19) United States
(12) Patent Application Publication
(10) Pub. No.: US 2023/0176259 A1
(43) Pub. Date: Jun. 8, 2023

(54) HARD SCRATCH AND SCUFF RESISTANT LOW REFLECTIVITY OPTICAL COATINGS

(71) Applicant: INTEVAC, INC., Santa Clara, CA (US)

(72) Inventors: Samuel D. Harkness, IV, Albany, CA (US); Tom Nolan, Santa Clara, CA (US); Jae Ha Choi, Pleasanton, CA (US); Alexander Vassilievich Demtchouk, Sunnyvale, CA (US); Terry Bluck, Santa Clara, CA (US)

(21) Appl. No.: 18/076,590

(22) Filed: Dec. 7, 2022

Related U.S. Application Data
(60) Provisional application No. 63/287,024, filed on Dec. 7, 2021.

(51) Int. Cl. G02B 1/14; G02B 1/11

(52) U.S. Cl. CPC G02B 1/14; G02B 1/11

(57) ABSTRACT

A protective coating for transparent panels, especially beneficial for transparent panels covering digital displays. The protective coating includes an adhesion layer formed on a surface of the transparent panel, a stress grading intermediate layer formed over the adhesion layer, a protective layer formed over the stress grading intermediate layer, and an antireflective layer formed over the protective layer. Also provided is a sputtering system for fabricating the protective coating.

### RELATED APPLICATIONS

This Application claims priority from U.S. Provisional Application Ser. No. 63/287,024, filed on Dec. 7, 2021, the disclosure of which is incorporated herein by reference in its entirety.

### BACKGROUND

### Field

This Application relates to coatings for protection of transparent panels, especially transparent panels used in electronics devices.

### Related Arts

With the huge popularity of mobile devices, such as, cell phones, smart watches, VR goggles and other devices, which have optical displays, there is a growing need to protect these devices from handling damage which degrades their appeal. Transparent panels (glass or plastic) that are used to protect optical displays need to be optically clear, have high transmission, low reflectivity, and be scratch and scuff resistant. The resistance of the panels to scratch and scuff can be enhanced using coatings which does not degrade the optical properties of the panel.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide coatings made of various layers of materials that function together to enhance the scratch and scuff resistance of transparent panels. The coatings do not degrade, and indeed even enhance the optical properties of the transparent panels. When applied to a transparent panel, the optical properties improve in that the transmittance through the protective film and the panel is higher than the transmittance through the panel without said film. This is due, at least in part, to the inclusion of anti-reflective layer in the stack of the protective coating. Also disclosed are embodiments for equipment used to efficiently coat the transparent substrates.

Disclosed embodiments provide a transparent protective coating having an adhesion layer, a stress grading layer, a protective layer, and an anti-reflective layer. In disclosed embodiments the adhesion layer includes an oxide containing layer having refractive index n smaller than 1.65. The adhesion layer includes no nitrogen and, in some embodiments, the refractive index is set below 1.5. The stress grading intermediate layer consists of an oxide containing layer having refractive index n lower than the protective layer. The protective layer has a thickness of at least three times the stress grading intermediate layer and refractive index higher than the stress grading intermediate layer. The anti-reflective layer comprises a plurality of sublayers, wherein at least one sublayer has a refractive index higher than the protective layer and at least one sublayer has a refractive index lower than the protective layer.

Disclosed embodiments also provide a transparent coating that enables forming anti-reflective coating on plastic substrates with improved longevity. A diffusion barrier is first deposited on the plastic substrate. The diffusion barrier inhibits substrate moisture from rising to the anti-reflective film surface and then denigrating the optical properties of the material. The diffusion barrier has low refractive index, e.g., below 1.65 by including a relatively high amount of oxygen and relatively low amount of nitrogen. In disclosed embodiments the barrier layer is made of SiAlOxNy, with low amount of Al and low amount of N, so that the resulting refractive index is below 1.65 or even below 1.55.

Disclosed embodiments also provide a method for fabricating protective coating, comprising the steps of: introducing a transparent substrate into a vacuum environment; exposing the substrate to plasma to cause ion species to bombard a top surface of the substrate; forming an adhesion layer by sputtering a silicon target; forming a stress grading layer on the adhesion layer by sputtering process of an SiAl target while injecting mixture of oxygen and nitrogen gas into sputtering plasma; forming a protective layer over the stress grading layer by sputtering process of an SiAl target while injecting a second mixture of oxygen and nitrogen gas into sputtering plasma; and forming an anti-reflective layer over the protective layer by sputtering process of an SiAl target while injecting a third mixture of oxygen and nitrogen gas into sputtering plasma.

With this disclosure, a sputtering system is provided, comprising: a vacuum chamber having a plurality of sputtering stations therein having unincumbered free fluid flow between the sputtering stations, each of the sputtering stations having two sputtering sources with targets made of the same material, and each of the sputtering stations having a gas injection manifold positioned between the two sputtering sources; a gas delivery manifold delivering a first gas and a second gas to each of the gas injection manifolds; a controller controlling a ratio of the first gas and the second gas delivered to each of the gas injection manifolds independently; a feedback loop measuring gas flow in each of the gas injection manifolds and sending corresponding signal to the controller; a loadlock mounted onto the vacuum chamber; and a gate valve sealingly attached between the vacuum chamber and the loadlock.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 schematically depicts a cross section of a protective coating, showing the various layers according to an embodiment;

FIG. 2 schematically depicts a cross section of a protective coating, showing the various layers according to another embodiment;

FIG. 3 schematically illustrates an embodiment of linear system for manufacturing the coatings disclosed herein; and,

FIG. 4 schematically illustrate an embodiment of endless-rotation type system for manufacturing the coatings disclosed herein.

### DETAILED DESCRIPTION

Various embodiments will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

In the embodiments disclosed, the various layers of the coatings are formed using sputtering process. Generally, the sputtering process itself is well known and employs a target made of the material sought to be deposited on the substrate - here the transparent panel. The target is bombarded so as to sputter material from the target, which then travels and lands on the substrate. Sputtering can be performed in what’s called “poison mode”, wherein the surface of the target is “poisoned” by interaction with gas present in the vicinity of the target, or metal mode, wherein the surface of the target remains purely of the target’s original material. For example, when using oxygen in the sputtering chamber, high flow rate of oxygen may cause the surface of the target to oxidize and thus sputter as oxides. Conversely, in metal mode the sputtering is of the pure target material and if oxidation is needed, it can be done later in the process by introducing the coated substrate to oxygen environment. The deposition rate of the poison mode is relatively lower than that of the metallic mode since ionic bonds are generally stronger than metallic ones. The choice of the proper mode to use may have effect on the quality of the final film deposited and of the flow and efficiency of the overall process.

The subject inventors have developed a novel approach to creating improved protective coating and the equipment to manufacture these coatings in a cost-effective high-volume way. In disclosed embodiments, the transparent plates to be coated are introduced into a vacuum process chamber via a loadlock or series of loadlocks, which enable maintaining the processing chamber in constant vacuum, while receiving and delivering panels from an atmospheric environment. The process chamber has a series of reactive sputter deposition sources for serially building the optical film stack. The substrates pass by, in a continuous line, in front of each process source, whereby each layer of the film stack is deposited consecutively. At each given time, the first layer is deposited on substrate nₓ at the same time as the last layer is deposited on substrate n_{y}, wherein substrate n_{y} was introduced into the chamber several cycles before substrate nₓ.

Unlike the prior art, wherein several vacuum chambers are used, one for each layer, here the sources for the layers are all within one vacuum chamber without valves to provide vacuum isolation between them. Rather, the reactive process for each source is controlled so that the composition is controlled for each layer independently and without cross-contamination. That is, if layer nᵢ is, for example, SiON with very low N content and layer nⱼ has higher N content and a lower O content, then the gas flow into each source in the line of sources is controlled such that the desired change in composition is achieved without crossflow of unwanted gas species.

In disclosed embodiments the system can be an inline system, wherein panels are introduced into vacuum in one end and exit at the other end, with every layer having an independent process source. Conversely, the system can be configured with an oval path, wherein panels enter and exit the system from the same side, but preferably using independent loadlocks. Once inside the vacuum environment, the substrates move linearly past the sources, but the process in each source is controlled independently depending on the layers being deposited. In some embodiments the oval system allows for the same stack to be created by making multiple trips around the oval with the process changing for each pass. Such an implementation is more akin to batch processing, wherein at each given time all of the substrates are coated with the same material concurrently. Then at the next step the deposition material can be changed and all the substrates receive a new layer concurrently.

As will be disclosed in more details below, the film stack contains SiOx and SiAlOxNy in various compositions. It is reactively sputtered from silicon (Si) and silicon-aluminum (SiAl) targets. In disclosed embodiments all of the targets contain from 3% to 15% aluminum. The aluminum in the target has several functions: it helps control the hardness stress, refractive index and fabrication of the targets. Without aluminum in the target the cost to manufacture is greatly increased.

By controlling the different mixtures that are deposited on the panels, the refractive index can be specifically tailored. The refractive index range for SiON can be controlled to from about 1.46 of SiOx to about 2.0 for Si3N4. The refractive index range for AlON can be controlled to from about 1.68 for Al2O3 to about 2 AlN. The refractive index range for SiAlOxNy can be controlled to from about 1.48 for SiAlOx) to about 2.0 for SiAlNx. Relatively low amount of nitrogen flow is required to achieve the higher refractive indexes, so process control with the single process chamber is easier to achieve.

In disclosed embodiments the panel is coated with four layers: an adhesion layer, a stress grading layer, a protective layer, and an anti-reflective layer. After an optional plasma cleaning of the substrate, an adhesion layer formed on a surface of the substrate. Then a stress grading intermediate layer is formed over the adhesion layer. This is followed by a protective layer that is formed over the stress grading intermediate layer. Finally, an anti-reflective layer is formed over the protective layer. With such arrangement, the adhesion and stress grading layers enhance the integrity and longevity of the coating, the protective layer enhances the scratch and scuff resistance of the panel, and the anti-reflective layer enhances the optical properties of the panel.

In disclosed embodiments the adhesion layer includes an oxide containing layer having refractive index n smaller than 1.65. The adhesion layer includes no nitrogen and, in some embodiments, the refractive index is set below 1.5. The stress grading intermediate layer consists of an oxide containing layer having refractive index n lower than the protective layer. The protective layer has a thickness of at least three times the stress grading intermediate layer and refractive index higher than the stress grading intermediate layer. The anti-reflective layer comprises a plurality of sublayers, wherein at least one sublayer has a refractive index higher than the protective layer and at least one sublayer has a refractive index lower than the protective layer.

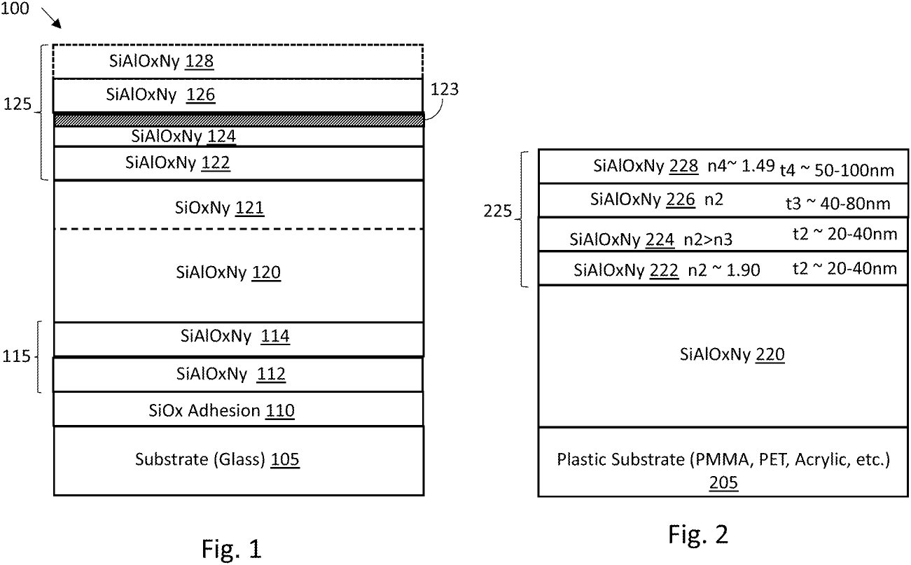

FIG. 1 schematically depicts a cross section of a protective coating, showing the various layers according to an embodiment. In this embodiment the coating is applied to a transparent panel substrate 105 made of glass. An adhesion layer 110 is formed over the surface of the substrate. The adhesion layer is made of SiOx and may be sputtered in poison mode or metal mode. The adhesion layer is set to have refractive index, n, of less than 1.65 or even less than 1.50. For example, the adhesion layer has refractive index of 1.48. In disclosed embodiments, the refractive index of the adhesion layer is not more than 0.005 higher than the refractive index of the substrate and is not more than 0.005 lower than the refractive index of the substrate. The thickness of the adhesion layer 110 is set to from 40 nm to 80 nm and the thin film stress of the adhesion layer is set to less than 100 mPa.

Next a stress grading layer 115 is formed by sputtering two sub-layers 112 and 114 over the adhesion layer. The stress grading layer 115 grades the stress through multiple sublayers so that no interfacial energy or stress is too high. The two sub-layers are made of SiAlOxNy films but have different refractive index. The first sublayer is made of SiAlOxNy wherein the oxygen and nitrogen flow are adjusted to control the relative OxNy composition to obtain the desired refractive index. The stress grading layer is designed so as to have a refractive index that while is higher than that of the adhesion layer, is not as high as that of the protective layer so as to serve as a “buffer” between the adhesion and protection layers and thereby relieve stress that would have been present if the protection layer was to be formed directly on the adhesion layer.

In the example shown in FIG. 1, the first sublayer 112 is formed to have a refractive index n1 that is higher than that of the adhesion layer, here higher than 1.48, but lower than the active index n2 of the second sublayer 114, which is still lower than the refractive index n3 of the protective layer, so that n3 > n2 > n1 > n. To achieve this result, either or both the ratio of nitrogen to oxygen or/and the ratio of aluminum to silicon is/are increased for each successive layer. In some embodiments, the refractive index of the stress grading layer 115 or of sublayer 112 substantially matches the index of the top surface of the optically transmissive substrate 105. In alternative embodiments, the refractive index of the stress grading layer 115 or of sublayer 112 is not more than 0.005 higher than that of the substrate and is not more than 0.005 lower than that of the substrate. The first sublayer 112 is formed to a thickness of 40-200 nm and the second sublayer 114 is formed to have a thickness of 50-200 nm. IN some embodiments the total thickness of the stress grading layer 115 is at least 200 nm, while in other embodiment it is at least 1000 nm. In some embodiments the thin film stress of the stress grading layer 115 is less than 100 mPa. In some embodiments the stress grading layer 115 comprises a film having film porosity of at least 10%. In some embodiments the stress grading layer 115 comprises material sputter deposited at a pressure of at least 10 mT and having a thermal conductivity value k<0.0001.

The protection layer 120 is formed over the stress grading layer 115, and is relatively thick to have a thickness of at least three times the stress grading layer 115, here 2-4 microns. The protective layer 120 is made of SiAlOxNy wherein the oxygen and nitrogen flow are adjusted to control the relative OxNy composition to obtain a refractive index n3 that is higher than the refractive index of all of the preceding layers. The protective layer may have refractive index of from about 1.65 to about 1.80 or from about 1.65 to about 1.70.

In another embodiment, illustrated by the dashed line in FIG. 1, the protective layer is formed of two sublayers, a first sublayer 120 as described above, and a second sublayer 121 made of SiON.

A hardened anti-reflective coating 125 is formed over the protective coating and is made of several sublayers made of SiAlOxNy having alternating refractive indices. Specifically, the first sublayer 122, which is formed directly on the protective layer, is set to have a refractive index n4 that is higher than that of the protective layer 120, i.e., n4 > n3. The first sublayer is formed to have a thickness of 20-40 nm. The second sublayer 124, that is formed directly on the first sublayer 122, has a refractive index n5 that is lower than that of the first sublayer 122, i.e., n4 > n5 > n3. The second sublayer 124 is formed to have a thickness of 20-40 nm. The third sublayer 126, that is formed directly on the second sublayer 124, has a refractive index that is the same as that of the first sublayer, i.e., n4. The third sublayer 126 is formed to a thickness of 40-80 nm. The fourth sublayer 128, i.e., top layer of the stack, has a refractive index the same as that of the first stress grading sublayer 112, i.e., n1. In a further embodiment, the fourth sublayer may be omitted, as indicated by the dotted lines. Also, as illustrated by gradient 123, at least one of the sublayers of the anti-reflective layer 125 comprises a dual-layer structure including a main layer (e.g., layer 124) and a thinner grading layer having a refractive index between that of the main layer (i.e., 124) and the abutting layer (here 126). This arrangement can be applied to any of the sublayers of the anti-reflective coating.

The hard coat layer index and thickness may be modified for different substrates and applications. Optical structure indices and thicknesses may vary slightly with index of alternative glass-like material. For example, variations can be implemented for a substrate made of plastic, such as PMMA (Poly(methyl methacrylate)), PET (Polyethylene terephthalate), Acrylic, etc. Sometimes it is desirable to apply an inorganic anti-reflective coating to an organic transparent substrate. The inorganic coating provides enhanced scratch resistance than the organic substrate, but can be damaged when moisture from the organic substrate rises to the inorganic film surface and denigrates the material. FIG. 2 illustrates an embodiment of a protective film formed on an organic plastic substrate.

In the embodiment of FIG. 2, the plastic substrate has a given refractive index n, depending on the plastic material. In this embodiment, a barrier layer 220 if deposited on the surface of the substrate, having refractive index n1 that is adjusted to match that of the plastic substrate, i.e., n1 = n. The barrier layer 220 is made of SiAlOxNy, but to achieve the matching of the refractive index of the plastic (which is relatively low), the amount of Al and N are set to relatively low level compared to the amount of Si and O. The barrier layer is formed to have a thickness of 2-4 microns.

A hardened anti-reflective layer 225 is then formed over the barrier layer 220 and is made of several sublayers of SiAlOxNy having alternating low/high refractive indices. Specifically, the first sublayer 222, which is formed directly on the barrier layer 220, is set to have a relatively high refractive index n2 of about 1.90 and having thickness of about 20-40 nm. The second sublayer 224, that is formed directly on the first sublayer 222, has a refractive index n3 that is lower than that of the first sublayer 222, i.e., n2 > n3. The second sublayer 224 is formed to have a thickness of 20-40 nm. The third sublayer 226, that is formed directly on the second sublayer 224, has a refractive index that is the same as that of the first sublayer, i.e., n2. The third sublayer 226 is formed to a thickness of 40-80 nm. The fourth sublayer 228, i.e., top layer of the stack, has a relatively low refractive index of about 1.49. The fourth sublayer 228 is formed to have a thickness of about 50-100 nm.

All of the SiAlOxNy films in these embodiments are sputtered in “metal mode” at constant voltage with feedback control of oxygen flow for high-rate uniform index film deposition. The hard coat layer index and thickness may be modified for different substrates and applications. The optical structure indices and thicknesses may vary slightly with index of alternative glass-like material. An Ar-O inductively coupled plasma (ICP) cleaning process may be applied to glass substrates as needed. Additionally, plasma can be used to provide a reduced interface energy on the surface of the substrate at the interface with the adhesion layer by energetic bombardment of ions from the plasma prior to adhesion layer deposition.

For plastic substrates, the index matched SiAlOxNy low stress adhesion protective layer is sputtered in “metal mode”. The SiAlOxNy anti-reflective hard coat is sputtered in “metal mode” at constant voltage with oxygen flow control for high-rate uniform index film deposition. The optical structure indices and thicknesses may vary slightly with index of alternative glass-like material. An N2 gas ICP adhesion/cleaning may be applied as needed.

With this disclosure, a transparent panel is provided, comprising: a transparent plate made of plastic; a barrier layer formed over major surface of the transparent plate, the barrier layer made of material comprising at least silicon and oxygen and having a refractive index matching the refractive index of the transparent plate; an anti-reflective layer formed over the barrier layer, the refractive index made of a plurality of sublayers made of SiAlOxNy, wherein each sublayer has different ratio of x/y, such that sublayer having x/y ratio resulting in high refractive index are interlaced with sublayers having x/y ratio resulting in lower refractive index. The barrier layer may comprise SiAlOxNy, wherein the amount of Al and N are adjusted to result in the barrier layer having refractive index matching the refractive index of the transparent plate. The refractive index of the barrier layer may be less than 1.60 and may have a thickness of 2-4 microns. A top sublayer of the anti-reflective layer may have a refractive index of less than 1.50 and a first sublayer of the anti-reflective layer which contacts the barrier layer may have a refractive index of at least 1.90. Each sublayer of the anti-reflective layer may have a thickness of 100 nm or less.

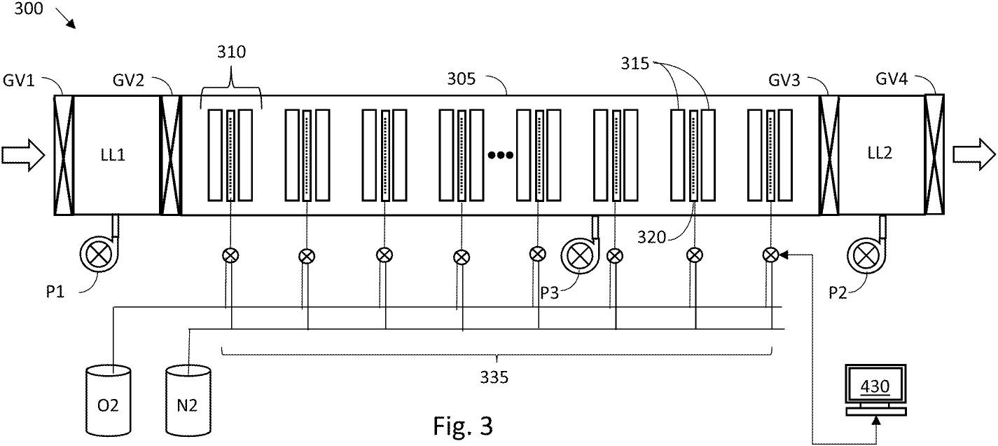

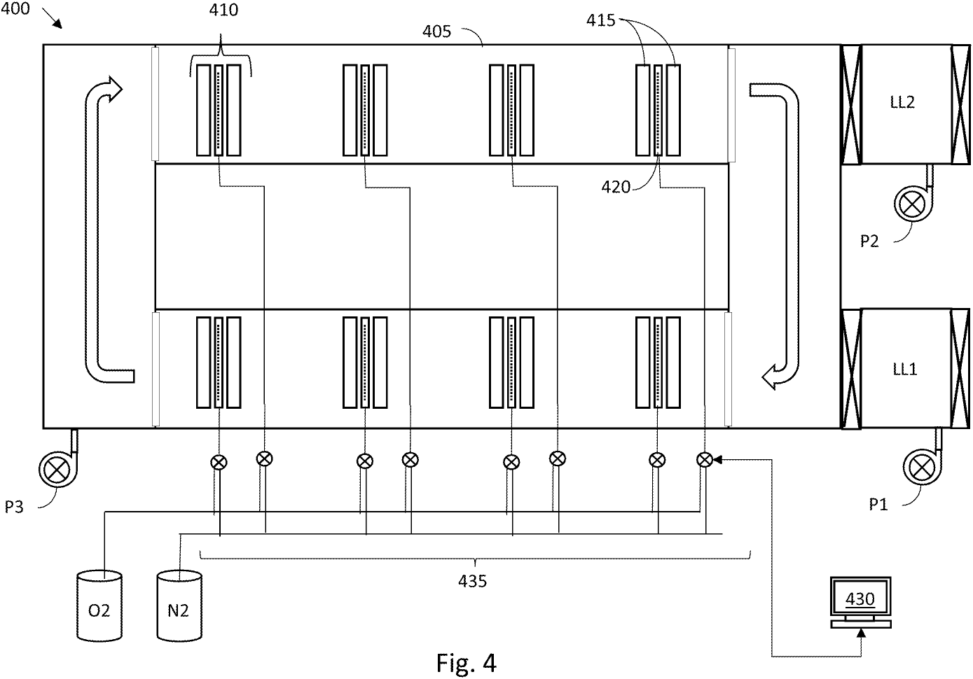

FIG. 3 schematically illustrates a top view of an embodiment of a system 300 for forming the protective optical coating disclosed herein. The embodiment depicted in FIG. 3 shows a linear processing architecture, wherein substrates enter the system through a loadlock, here LL1, at one end of the system, and exit through a second loadlock, here LL2 at the other end of the system. Each loadlock has a gate valve (GV1-GV4) at its entrance and a gate vale at its exit, with its own vacuum pumping and venting facility (P1 and P2).

The system is formed of a single vacuum chamber 305, in which multiple sputtering stations 310 are positioned with no partitions and/or gate valves in between the stations. The vacuum chamber 305 has its own vacuum pumping and venting facility P3. The number of sputtering stations 310 may vary depending on the number of layers to be deposited, as indicated by the ellipsis. As shown in FIG. 3, each sputtering station 310 has two cathodes 315, each having an elongated SiAl target mounted thereto. A gas injection manifold 320 is positioned between the two cathodes 315 in each station. In operation, the gas flow is monitored in a closed loop by controller 330 so that the amount of gas supplied is consumed by the deposition process at that station and does not flow to neighboring stations. In this manner, each processing station can deposit a film having different SiAlOxNy composition, thus having different refractive index. A substantial benefit of this arrangement is that no time is wasted on opening and closing gate valves in between stations, as is done in the prior art. Thus, fabrication time is vastly increased.

With the arrangement of FIG. 3, the N2 and O2 gases are introduced at different ratios for each particular cathode pair, depending on the desire composition. The depositing film consumes most of the reactants (N & O), so the depositing film acts a virtual gas flow restriction, greatly minimizing the reactants that escape a particular pair. The cathode pairs further act as “restrictions” as the upstream cathode consumes excess N:O and the downstream consumes excess N:O with the resulting film composition being a mixture of the small amount of upstream/downstream gases plus the gases that are directly introduced between the pairs. The composition is predominately drive by the directly introduced gas.

With the embodiment of FIG. 3, a sputtering system is provided comprising a vacuum chamber 305 having a plurality of sputtering stations 310 therein, the vacuum chamber having unincumbered free fluid flow between the sputtering stations as shown by lack of any gate valve between the stations 310. Each of the sputtering stations has two sputtering sources 315 with targets made of the same material, and each of the sputtering stations 310 having a gas injection manifold 320 positioned between the two sputtering sources 315. The gas delivery manifold 335 delivers a first gas (e.g., O2) and a second gas (e.g., N2) to each of the gas injection manifolds 320. A controller 430 controls a ratio of the first gas and the second gas delivered to each of the gas injection manifolds 320 independently. A feedback loop measures gas flow in each of the gas injection manifolds and sends a corresponding signal to the controller, as exemplified by the double-headed arrow. A loadlock (e.g., LL1) is mounted onto the vacuum chamber and a gate valve (e.g., GVs) is sealingly attached between the vacuum chamber 305 and the loadlock.

FIG. 4 illustrates another embodiment of a system 400, which uses a racetrack-type architecture, so that each substrate can pass under a given processing station multiple times. In this alternate system configuration, the system can be configured for operation in a batch mode. The process chamber is loaded with substrates, and the substrates move around and around the oval track until the desired number of layers is created. Then the substrates are swapped with new substrates. The gas isolation/restriction occurs in exactly the same way as in the linear system; however, in the batch process system each pass thru the system can have a different compositional mix with the layers created in that pass. For example, in a first step all of the modules 410 are operated with the same nitrogen/oxygen flow ratio, as controlled by controller 430, so that the same type of layer is formed on all of the substrates concurrently. Then the nitrogen/oxygen flow ratio is changed to a new ratio for all of the modules, and a second layer is formed on all of the substrates concurrently. In this way, the entire stack can be fabricated on multiple substrates concurrently and when the entire stack is completed, all of the substrates exit the system via loadlock LL2 and new substrates enter the system via loadlock LL1.

As in the linear arrangement of FIG. 3, the SiAl cathodes 415 are arranged in pairs n each sputtering station 410. Each pair deposits a SiAlO_{y}Nₓ with different y and x as determined by the gas O:N flow ratio thru the injection manifold 420. Each of the gas distribution manifolds 420 is located between a pair of cathodes 415 to confine the gas flow to be consumed at the sputtering station and not flow to neighboring stations.

With this disclosure, a sputtering system is provided, comprising: a vacuum chamber having a plurality of sputtering stations therein having unincumbered free fluid flow between the sputtering stations, each of the sputtering stations having two sputtering sources with targets made of the same material, and each of the sputtering stations having a gas injection manifold positioned between the two sputtering sources; a gas delivery manifold delivering a first gas and a second gas to each of the gas injection manifolds; a controller controlling a ratio of the first gas and the second gas delivered to each of the gas injection manifolds independently; a feedback loop measuring gas flow in each of the gas injection manifolds and sending corresponding signal to the controller; a loadlock mounted onto the vacuum chamber; and a gate valve sealingly attached between the vacuum chamber and the loadlock.

Also, disclosed embodiments also provide a method for fabricating protective coating, comprising the steps of: introducing a transparent substrate into a vacuum environment; exposing the substrate to plasma to cause ion species to bombard a top surface of the substrate; forming an adhesion layer by sputtering a silicon target; forming a stress grading layer on the adhesion layer by sputtering process of an SiAl target while injecting mixture of oxygen and nitrogen gas into sputtering plasma; forming a protective layer over the stress grading layer by sputtering process of an SiAl target while injecting a second mixture of oxygen and nitrogen gas into sputtering plasma; and forming an anti-reflective layer over the protective layer by sputtering process of an SiAl target while injecting a third mixture of oxygen and nitrogen gas into sputtering plasma. As exemplified by the embodiments of FIGS. 3 and 4, for each layer the SiAl target may be a different or the same target, depending on the chamber architecture. Thus, the mixture of oxygen and nitrogen gas for the different layers may be injected into the same or different sputtering target, depending on the architecture used.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A protective film for an optically transmissive substrate, comprising:
an adhesion layer formed on a surface of the substrate;
a stress grading intermediate layer formed over the adhesion layer;
a protective layer formed over the stress grading intermediate layer; and,
an anti-reflective layer formed over the protective layer; wherein:
the adhesion layer includes an oxide containing layer having refractive index n smaller than 1.65;
the stress grading intermediate layer consists of an oxide containing layer having refractive index n lower than refractive index of the protective layer;
the protective layer has a thickness of at least three times the stress grading intermediate layer and refractive index higher than the stress grading intermediate layer;
the anti-reflective layer comprises a plurality of sublayers, wherein at least one sublayer has a refractive index higher than said protective layer and at least one sublayer has a refractive index lower than said protective layer.

2. The protective film according to claim 1, wherein the adhesion layer comprises silicon and oxide.

3. The protective film according to claim 2, wherein the adhesion layer further comprises aluminum.

4. The protective film according to claim 1, wherein the protective layer comprises AlSiON.

5. The protective film according to claim 4, wherein the protective layer has refractive index of from about 1.65 to 1.70.

6. The protective film according to claim 1, wherein the protective layer comprises two sublayers, a first sublayer comprising AlSiON and a second sublayer comprising SiON.

7. The protective film according to claim 1, wherein a sublayer abating the protective layer has a refractive index higher than the protective layer.

8. The protective film according to claim 1, wherein the anti-reflective layer comprises three sublayers, a first sublayer abating the protective layer has a refractive index higher than the protective layer, a second sublayer abating the first sublayer has a refractive index higher than the first sublayer, and a third sublayer abating the second sublayer has a refractive index lower than the protective layer.

9. The protective film according to claim 1, wherein the anti-reflective layer comprises four sublayers, a first sublayer abutting the protective layer has a refractive index higher than the protective layer, a second sublayer abutting the first sublayer has a refractive index higher than the protective layer but lower than the first sublayer, a third sublayer abutting the second sublayer has a refractive index higher than the second sublayer, and a fourth sublayer abutting the third sublayer has a refractive index lower than the protective layer.

10. The protective film according to claim 1, wherein at least one sublayer of the anti-reflective layer comprises a dual-layer structure including a main layer and a thinner grading layer having a refractive index between that of the main layer and the abutting layer.

11. The protective film according to claim 1, wherein the transmittance through said protective film and said substrate is higher than the transmittance through said substrate without said film.

12. The protective film according to claim 1, wherein the refractive index of said adhesion layer substantially matches the index of a top surface of said optically transmissive substrate.

13. The protective film according to claim 12, wherein the refractive index of said adhesion layer is not more than 0.005 higher than refractive index of said substrate and is not more than 0.005 lower than refractive index of said substrate.

14. The protective film according to claim 1, wherein a thin film stress of said adhesion layer is less than 100 mPa.

15. The protective film according to claim 1, wherein the refractive index of said stress grading layer substantially matches the index of a top surface of said optically transmissive substrate.

16. The protective film according to claim 15, wherein the refractive index of said stress grading layer is not more than 0.005 higher than said substrate and is not more than 0.005 lower than said substrate.

17. The protective film according to claim 1, wherein a thin film stress of said stress grading layer is less than 100 mPa.

18. The protective film according to claim 1, wherein said stress grading layer comprises a film having film porosity of at least 10%.

19. The protective film according to claim 1, wherein the stress grading layer comprises AlSiON.

20. The protective film according to claim 1, wherein the stress grading layer comprises a material sputter deposited at a pressure of at least 10 mT and having a thermal conductivity value k<0.0001.

21. The protective film according to claim 1, wherein the stress grading layer comprises at least 200 nm thickness.

22. The protective film according to claim 1, wherein the stress grading layer comprises at least 1000 nm thickness.

23. The protective film according to claim 1, wherein the substrate comprises a reduced interface energy with said adhesion layer provided by energetic bombardment prior to adhesion layer deposition.

24. The protective film according to claim 23, wherein said reduced interface energy provided by energetic bombardment prior to adhesion layer deposition comprises ICP employing a carrier gas including N2.

25. The protective film according to claim 1, wherein the adhesion layer contains no nitrogen and has a refractive index smaller than 1.5.
